(19) United States
(12) Patent Application Publication
(10) Pub. No.: US 2002/0061112 A1
(43) Pub. Date: May 23, 2002

(54) Dynamics reduction for dynamics-limited audio systems

(75) Inventor: Michael Walker, Baltmannsweiler 2 (DE)

Correspondence Address: SUGHRUE, MION, ZINN, MACKEAK & SEAS, PLLC, 2100 Pennsylvania Avenue, N.W., Washington, DC, 20037-3213, US

(73) Assignee: ALCATEL

(21) Appl. No.: 09/970,693

(22) Filed: Oct. 5, 2001

(30) Foreign Application Priority Data
Oct. 11, 2000 (DE) 100 50 150.8

(51) Int. Cl. H03G 7/00

(52) U.S. Cl. 381/106

(57) ABSTRACT

A method for limiting the dynamic response of audio signals in audio terminals, wherein an input signal x is treated such that a defined maximum limit value yₘₐₓ for an output signal y from the terminal is not exceeded, and wherein a predeterminable constant amplification value v is set, where for v≦1 the input signal x with a nominal level is reproduced with maximum amplitude≦yₘₐₓ without distortion as output signal y, and where for v=const>1 a distortion of the signals occurs. In a first step the input signal x is compressed in its dynamic response to an intermediate value y₁<x, and in a following second step the output signal y=v * y₁, amplified with the constant amplification value v, is formed.

The invention is based on a Priority application DE 100 50 150.8 which is hereby incorporated by reference.

### FIELD OF THE INVENTION

The invention relates to a method for limiting or reducing the dynamic response of audio signals, in particular human speech signals, in audio terminals, in particular in telecommunications (=TC) terminals for the transmission of acoustic useful signals, wherein an input signal x is treated such that a defined maximum limit value yₘₐₓ for an output signal y from the terminal is not exceeded, and wherein a pre-determinable constant amplification value v is set, where for v≦1 the input signal x with a nominal level is reproduced with maximum amplitude≦yₘₐₓ without distortion as output signal y and where for v=const>1 a distortion of the signals occurs.

### BACKGROUND OF THE INVENTION

A method of this kind is known for example through the so-called hard clipper principle.

In accordance with the hard clipper principle, as shown in FIG. 1b, the audio signals are hard limited to a fixed value. In analogue technology the limitation generally occurs by limiting the available supply voltage or is set at a fixed value by means of the limiter circuit. In digital signal processing the digital sample values must be limited to a maximum representable value in order to prevent a number overflow. The hard limitation gives rise to audible distortions and the speech quality and intelligibility are impaired.

In the case of the recording of audio signals on magnetic tape, the dynamic scope is limited by the physical properties of the tape material. In the known DOLBY process, a dynamic compression with a fixed degree of compression is performed prior to the recording onto a magnetic tape. After reading from the magnetic tape, the recording is restored to the original dynamic range by means of dynamic expanders. Compression degree and expansion degree cancel one another out. However this results in the following disadvantages: A fixed compression changes the loudness in the entire dynamic range and leads to “breathing”. The objective should however be to transmit the entire range as true to nature as possible. However, there is no automatic adaptation to the available dynamic range in the DOLBY process.

Dynamics reduction processes for digital audio signals with a-law or μ-law compression characteristics are known in accordance with the standard ITU-T G 721. They provide for data reduction to 64 kbit/s. Here the dynamic range is compressed by 6 bits corresponding to 36 dB prior to the transmission and decompressed again with the same characteristic following the transmission.

These methods are disadvantageous inasmuch as a distortion occurs of each individual sample value corresponding to the non-linear function of the characteristic curve, leading to strong, audible distortions in the output signal y.

### SUMMARY OF THE INVENTION

In contrast, the object of the present invention is to further develop a method of the type described in the introduction with the simplest possible means, such that distortions in the output signal y are considerably reduced, if possible minimised, or entirely eliminated even for high amplifications v.

In accordance with the invention, this object is achieved in an equally surprisingly simple and effective manner, in that in a first step (a) the input signal x is compressed in its dynamic range to an intermediate value y₁<x, and that in a following second step (b) the output signal y=v * y₁, amplified with the constant amplification value v, is formed.

The amplification value v serves for loudness adjustment and is defined such that v=1 corresponds to the full modulation of a signal, where v>1 leads to distortions of a signal with nominal level.

Speech signals possess level fluctuations which are caused by the individual stress of the speaker. These quiet and loud passages must now be treated differently in order to achieve a maximum and distortion-free amplification for all passages.

However, the signal form of the speech signal is to be transmitted as faithfully as possible. The signal form is dependent upon the speech content (vowel, consonant etc . . . ).

With y₁, in accordance with the invention, from the input signal x an intermediate value is calculated which, in the subsequent amplification v, supplies distortion-free signals. For this purpose the dynamic response of the input signal x must be compressed to a value dependent upon the scenario. The required degree of compression or the required threshold from which the signal is compressed is dependent upon the signal content of x and upon the set amplification v. The type of compression can be individually defined.

A preferred variant of the method according to the invention is that in which an intermediate value y₁ is formed from y₁=x * f(cf), where f(cf) is a function of a dynamic amplification factor cf which is calculated in dependence upon the input signal x and the constant amplification value v.

For the formation of the intermediate value, the input signal x is reduced to a value dependent upon the amplification v, in order to avoid distortions due to over-modulation in the subsequent multiplication by cf.

A further development of this method variant provides that a short-time mean value sam(x) is formed from the input signal x, and that

for v≦1, the dynamic amplification factor cf is calculated as

cf=1/v,

for v>1 the dynamic amplification factor cf is calculated as

cf=1/(v² * sam(x)),

and the intermediate value y1=x * f(cf) is in each case formed therefrom.

The use of the short-time mean values sam(x) to calculate the current amplification factor cf facilitates a virtually distortion-free level control.

Individual sample values are considered stationarily and treated with approximately the same degree of amplification. This avoids audible signal form distortions, while the system adapts very rapidly to level fluctuations.

The system appears stable for individual sections, yet rapid system fluctuations can be corrected virtually inaudibly. The reason for this is the use of the sam-averaging adapted to the ear.

In systems with subsampled auxiliary values, this approach is simpler as no other conditional operations are required.

A simplification of this method variant provides that the output signal y is calculated directly from the input signal x and the amplification value v when v<1

y=v * x.

Otherwise

cf=1/(v² * sam(x))

and the output signal y=x * f(cf) is in each case formed therefrom.

If there is no risk of over-modulation, the output signal can be directly calculated from x and v. An advantage of this procedure is that no influencing of the signal in the event of amplification values v<1 occurs.

In another further development of the above described method variant, it is provided that a short-time mean value sam(x) is formed from the input signal x and that

for abs(x)≧1/v the dynamic amplification factor cf is calculated as

cf=1/v,

for abs(x)<1/v the dynamic amplification factor cf is calculated as

cf=1/(v² * sam(x)ⁿ),

where

|n|ε [symbol] ≠0

and the output signal y1=x * f(cf) is in each case formed therefrom. In this way the degree of compensation can be freely defined within relatively wide limits by the process according to the invention.

In a particularly simple implementation of this further development the exponent n=1 is selected.

In another, particularly preferred embodiment of the method according to the invention, the function f(cf) is selected such that it effects a filtering, in particular a smoothing, of the dynamic amplification factor cf.

In a particularly effective and easily handled further development of this embodiment the function f(cf) is a recursive filter of the first order for cf.

The smoothing is effective in all cases in which there is no over-modulation and reduces the distortion factor.

In particular, this further development can be further improved in that the input signal x is sampled in equidistant time steps T in each case at times k with a sampling frequency f_{A}=1/T, and that the function f(cf) is calculated as smoothed amplification value cg(k) in accordance with

$$f ( cf ) = cg ( k ) = \{ \begin{matrix}cf & for sam ( x ) > 1 / v \\ cf ( k ) * as + cg ( k - 1 ) * bs & for cf < cg \\ cf ( k ) * al + cg ( k - 1 ) * bl & for cf \geq cg\end{matrix} \\ where as = 1 - bs = 1 - {e}_{k}^{- T / τ} with a time constant {τ}_{k} < {t}_{max} \\ and al = 1 - bl = 1 - {e}_{l}^{- T / τ} with a time constant {τ}_{l} > {t}_{min} .$$

This status-dependent filtering results in a rapid suppression of over-modulation in the event of large dynamics jumps, while for normal situations the time function of the smoothing filter is adapted to the ear and provides for a distortion-free reproduction.

It is also advantageous if the sub-functions in the process for calculating the smoothed dynamic amplification value cg are calculated with a lower sampling frequency than f_{A} to save computing capacity.

To attain an acoustically adequate time response, the corresponding time limit values are advantageously selected as tₘₐₓ≦1 ms and tₘᵢₙ≧60 ms, preferably tₘᵢₙ≧65 ms.

In an alternative further development the function f(cf) comprises an integration f(cf)=∫cf * dt

or

$$a summation f ( cf ) = {K}^{- 1} * {\sum }_{k = 0}^{K - 1} cf ( k ) with K = T / {τ}_{m}$$

over cf.

A particularly preferred method variant is that in which the short-time mean value sam(x) is adapted to the perceptibility of the human ear in accordance with psycho-acoustics rules.

In another method variant it is advantageous for the input signal x to be sampled in equidistant time steps T in each case at times k with a sampling frequency f_{A}=1/T, and for the short-time mean value sam(x(k)) to be calculated in accordance with

$$sam ( x ( k ) ) = \{ \begin{matrix}x ( k ) * α s + sam ( x ( k - 1 ) ) * β s & for x ( k ) > sam ( x ( k ) ) \\ x ( k ) * α l + sam ( x ( k - 1 ) ) * β l & for x ( k ) \leq sam ( x ( k ) )\end{matrix} \\ where α s = 1 - β s = 1 - {e}_{k}^{- T / τ} with a time constant {τ}_{k} < {t}_{max} \\ and α l = 1 - β l = 1 - {e}_{l}^{- T / τ} with a time constant {τ}_{l} > {t}_{min} .$$

Here the time limit values again are preferably selected as tₘₐₓ≦1 ms and tₘᵢₙ≧60 ms, preferably tₘᵢₙ≧65 ms.

The scope of the present invention also includes a server unit, a processor module and a gate array module for supporting/executing the above described method according to the invention and a computer program for the execution of the method. The method can be implemented either as a hardware circuit or in the form of a computer program. Currently software programming for high-power DSPs is preferred as new findings and additional functions can be more easily implemented by changing the software on an existing hardware basis. However processes can also be implemented as hardware modules, for example in TC-terminals or telephone systems.

Further advantages of the invention will become apparent from the description and the drawing. Also the features referred to in the above and those referred to in the following can be used in accordance with the invention either individually or jointly in any combinations. The illustrated and described embodiments are not to be understood as a final specification but rather are to serve by way of example for the description of the invention.

### BRIEF DESCRIPTION OF THE DRAWINGS

The invention is illustrated in the drawing and will be explained in detail in the form of exemplary embodiments. In the drawing;

FIG. 1a is a highly schematised fundamental diagram of the mode of operation of a device for the execution of the process according to the invention;

FIG. 1b is a corresponding fundamental diagram for the prior art;

FIG. 2a illustrates the output signal level y as a function of the input signal x for different amplification values v in the process according to the invention;

FIG. 2b corresponds to FIG. 2a but according to the prior art;

FIG. 3a shows the modulation response of a strongly modulated speech signal after treatment with the process according to the invention and

FIG. 3b shows the modulation response of the same speech signal following treatment with a process according to the prior art.

### DESCRIPTION OF PREFERRED EMBODIMENTS

The object of the process according to the invention is the limitation or reduction of the dynamic response of audio signals, in particular human speech signals in all applications in which a limitation of the transmission dynamics exists.

Thus the distortion-free reproduction of speech signals with small loudspeaker systems or in terminals with limited supply voltage (battery-operated devices) is possible only in a limited modulation range. However, a greater loudness level than can be emitted by the system is often required, for example for quiet passages still to be audible in a noise-filled environment. This is only possible however by reducing the dynamic range.

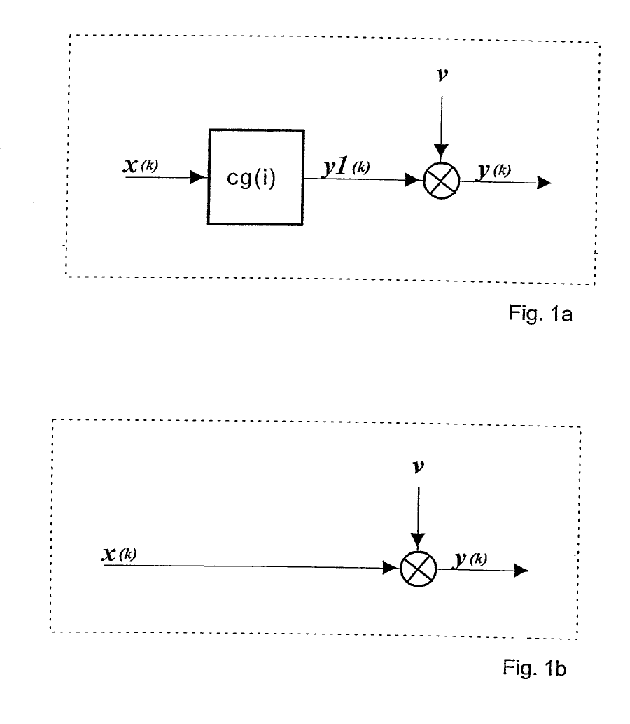

FIG. 1a illustrates the principle of the invention. Here the output signal y(k) is calculated as follows in accordance with Equation (1):

y(k=v*y₁(k) (1)

y₁(k) is the dynamics-reduced input signal and is calculated as follows in accordance with Equation (2):

$${y}_{1} ( k ) = \{ \begin{matrix}x ( k ) & if v \leq 1 \\ x ( k ) * f ( cf ( m ) ) & if v > 1\end{matrix} \qquad ( 2 )$$

The conditional decision in Equation (2) can also take place earlier. Thus the decision can take place as in Equation (1b), whereby the calculation of y₁(k) is simplified as follows and the best possible signal-to-noise ratio can be achieved:

$$\begin{matrix}y ( k ) = \{ \begin{matrix}x ( k ) * v & if v \leq 1 \\ v * {y}_{1} ( k ) & if v > 1\end{matrix} & \text{(1b)} \\ {y}_{1} ( k ) = x ( k ) * f ( cf ) & \text{(2b)}\end{matrix}$$

With y₁(k) a dynamically controlled signal is calculated, which can be amplified without distortion with the desired amplification. The dynamics compression is achieved by means of an averaged compression factor cf(m) which can be calculated as follows in accordance with Equation (3):

$$cf ( m ) = \{ \begin{matrix}1 / v & if \vert x ( k ) \vert < 1 / v \\ 1 / ( {v}^{2} * sam ( x ) ) & if \vert x ( k ) \vert \geq 1 / v\end{matrix} \qquad ( 3 )$$

The index m indicates that this value can be subsampled.

The averaging of cf(m) can be achieved as shown in the following Equation (4):

$${cg}_{( m )} = f ( {cf}_{( m )} ) = \{ \begin{matrix}cf & if ( \vert {x}_{( k )} \vert > \frac{1}{V} ) \\ cf ( m ) \cdot as + cg ( m ) \cdot bs & if {cf}_{( m )} < {cg}_{( m )} \\ cf ( m ) \cdot al + cg ( m ) \cdot bl & if {cf}_{( m )} > {cg}_{( m )}\end{matrix} \qquad ( 4 )$$

Two time constants are used. The coefficients as and bs stand for a short time constant and al and bl for a long time constant.

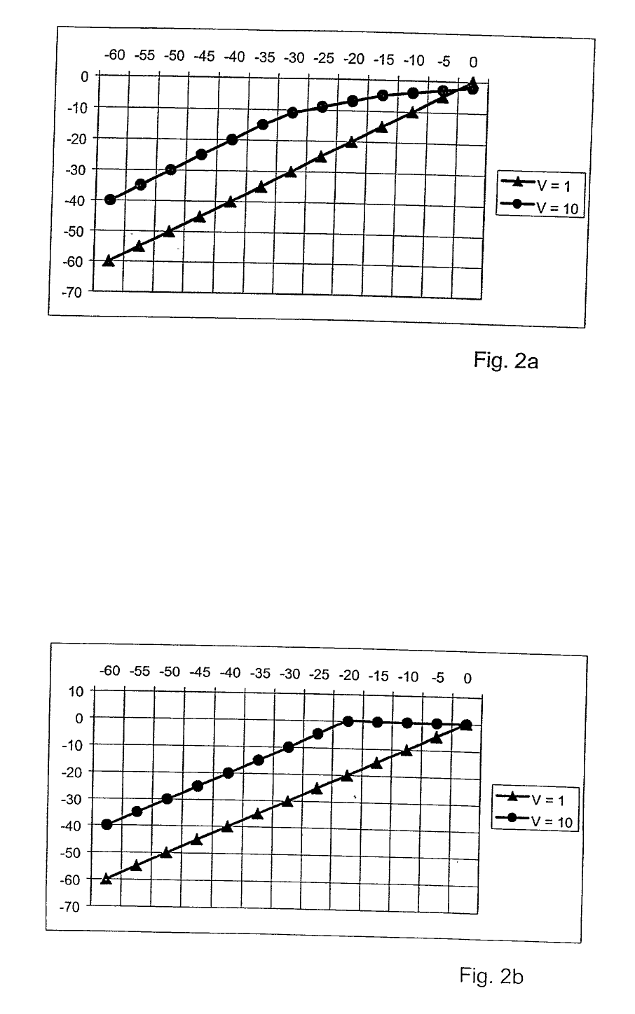

FIG. 2a illustrates the mode of operation of the invention when v=1 and v=10. Clearly shown is the bend from approximately −35 dB, from which the compression of the signal increases with increasing input level.

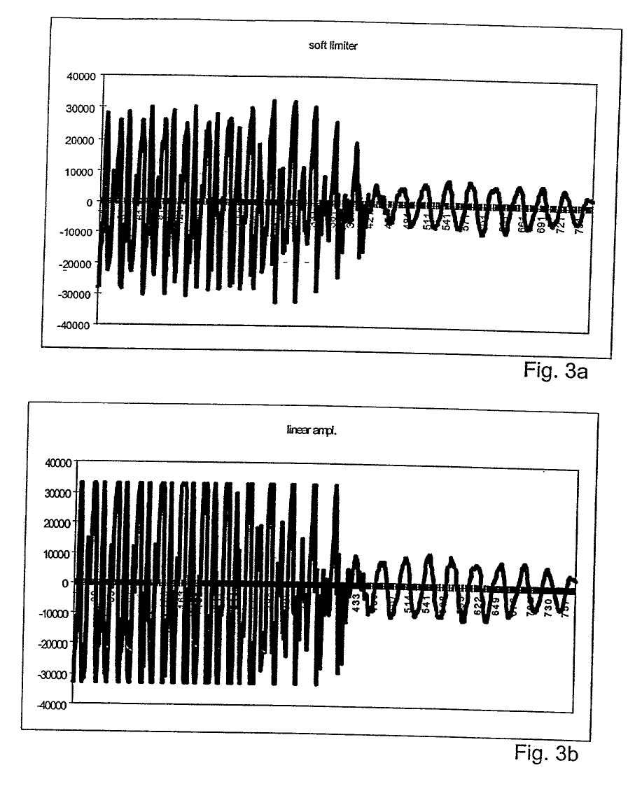

FIG. 3a shows the mode of operation of the invention in the time signal. The compression prevents loud signals being distorted, while quiet passages of the speech signal can still be distinctly amplified.

FIG. 1b illustrates the above described hard clipper principle.

FIG. 2b illustrates the effect of the hard clipper when v=1 and v=10. Here strong distortions occur already at −20 dB.

FIG. 3b finally illustrates the effect of the hard clipper in the case of a time signal.

1. A method for limiting or reducing the dynamic response of audio signals, in particular human speech signals, in audio terminals, in particular in telecommunications (=TC) terminals for the transmission of acoustic useful signals, wherein an input signal x is treated such that a defined maximum limit value yₘₐₓ for an output signal y from the terminal is not exceeded, and wherein a predeterminable constant amplification value v is set, where for v≦1 the input signal x with a nominal level is reproduced with a maximum amplitude≦yₘₐₓ without distortion as output signal y, and where for v=const>1 a distortion of the signals occurs, wherein in a first step the input signal x is compressed in its dynamic response to an intermediate value y₁<x, and in a following second step the output signal y=v * y₁, amplified with the constant amplification value v, is formed.

2. A method according to claim 1, forming the intermediate value y₁ from y₁=x * v⁻¹ * f(cf), where f(cf) is a function of a dynamic amplification factor cf which is calculated in dependence upon the input signal x and the constant amplification value v.

3. A method according to claim 2, forming a short-time mean value sam(x) from the input signal x and calculating
for v≦1 the dynamic amplification factor cf as cf=1/v, and
for v>1 the dynamic amplification factor cf as cf=1/(v² * sam(x))
and forming the output signal y=x * f(cf) therefrom.

4. A method according to claim 2, forming a short-time mean value sam(x) from the input signal x and calculating
for v>1 the dynamic amplification factor cf
as cf=1/(v²* sam(x)), and forming the output signal y=x * f(cf) therefrom,
and determining for v<1 the output signal y directly from y=v * X.

5. A method according to claim 2, forming a short-time mean value sam(x) from the input signal x and calculating
for sam(x)≧1/v the dynamic amplification factor cf as cf=1/v,
calculating for sam(x)<1/v the dynamic amplification factor cf as cf=1/(v² * sam(x)ⁿ)
where |n|ε [symbol] ≠0,
and forming the output signal y=x * f(cf) therefrom.

6. A method according to claim 3, sampling the input signal x in equidistant time steps T at times k with a sampling frequency f_{A}=1/T, and calculating the function f(cf) as smoothed amplification value cg(k) in accordance with
$$f ( cf ) = cg ( k ) = \{ \begin{matrix}cf & for sam ( x ) > 1 / v \\ cf ( k ) * ak + cg ( k - 1 ) * bk & for cf < cg \\ cf ( k ) * al + cg ( k - 1 ) * bl & for cf \geq cg\end{matrix} \\ where ak = 1 - bk = 1 - {e}_{k}^{- T / τ} with a time constant {τ}_{k} < {t}_{max} \\ and al = 1 - bl = 1 - {e}_{l}^{- T / τ} with a time constant {τ}_{l} > {t}_{min} .$$

7. A method according to claim 3, sampling the input signal x in equidistant time steps T at times k with a sampling frequency f_{A}=1/T, and calculating the short-time mean value sam(x(k)) in accordance with
$$sam ( x ( k ) ) = \{ \begin{matrix}x ( k ) * α k + sam ( x ( k - 1 ) ) * β k & for x ( k ) > sam ( x ( k ) ) \\ x ( k ) * α l + sam ( x ( k - 1 ) ) * β l & for x ( k ) \leq sam ( x ( k ) )\end{matrix} \\ where α k = 1 - β k = 1 - {e}_{k}^{- T / τ} with a time constant {τ}_{k} < {t}_{max} \\ and α l = 1 - β l = 1 - {e}_{l}^{- T / τ} with a time constant {τ}_{l} > min .$$

8. Server unit for executing said method according to claim 1.

9. Processor unit, in particular digital signal processor, for executing said method according to claim 1.

10. Programmable Gate-Array-Unit for executing said method according to claim 1.
